(19) United States
(12) Patent Application Publication
(10) Pub. No.: US 2008/0173917 A1
(43) Pub. Date: Jul. 24, 2008

(54) Selective deposition method

(76) Inventors: Matthias Patz, Dresden (DE); Alexey Ivanov, Dresden (DE); Stephan Kudelka, Dresden (DE)

Correspondence Address: JENKINS, WILSON, TAYLOR & HUNT, P. A., Suite 1200 UNIVERSITY TOWER, 3100 TOWER BLVD.,, DURHAM, NC, 27707, US

(21) Appl. No.: 11/655,664

(22) Filed: Jan. 19, 2007

(51) Int. Cl. H01L 27/108; H01L 21/334

(52) U.S. Cl. 257/301; 438/386; 257/E21.396; 257/E27.092

(57) ABSTRACT

The invention relates to a deposition method performing the following steps. A substrate is provided which is structured to comprise a first surface and a second surface, which differ in at least one of geometric orientation and vertical distance to a principle surface of the substrate. An etchable layer is deposited on the first surface via an atomic layer deposition technique the deposition technique using a first precursor supplied in an amount sufficient to cover at least parts of the first surface and insufficient to cover the second surface, the first precursor being supplied from a direction to pass the first surface before the second surface. A dielectric layer of at least one of a transition metal oxide and a transition metal nitride is deposited on at least the second surface via an atomic layer deposition technique using a second precursor.

### BACKGROUND OF THE INVENTION

1. Field of the Invention

The present invention relates to a selective deposition method, in particular for a transition-metal-containing dielectric.

2. Description of the Related Art

Although in principle applicable to arbitrary integrated semiconductor structures, the following invention and the underlying problems will be explained with respect to integrated DRAM memory circuits in silicon technology.

Memory cells of a DRAM device each comprise a capacitor for storing information encoded as electric charge retained in the capacitor. A reliable operation of the memory cells demands for a minimal capacitance of the capacitors and a sufficiently long retention time of the charge in the capacitors. Transition metal oxides provide good electrical characteristics for dielectrics used in such capacitors. The formation of contacts to electrodes of the capacitors demands for a clean partial removal of the dielectric. Some transition metal oxides deposited as dielectrics, however, do not form volatile products with standard etchants when crystallized.

### BRIEF SUMMARY OF THE INVENTION

The present invention provides a selective deposition method which can form a transition metal compound as dielectric in one area and a structurable compound in another area.

According to a first aspect of the invention, the selective deposition method performs the following steps. A substrate is provided which is structured to comprise a first surface and a second surface, which differ in at least one of geometric orientation and vertical distance to a principle surface of the substrate. An etchable layer is deposited on the first surface via an atomic layer deposition technique, the deposition technique using a first precursor supplied in an amount sufficient to cover at least parts of the first surface and insufficient to cover the second surface, the first precursor being supplied from a direction to pass the first surface before the second surface. A dielectric layer of at least one of a transition metal oxide and a transition metal nitride is deposited on at least the second surface via an atomic layer deposition technique using a second precursor.

The order of the deposition of the etchable layer and the dielectric layer can be interchanged and be repeated alternatingly for several times.

In the consecutive order, the first precursor may be applied to the first surface, the second precursor may be applied to the first surface and the second surface, and an oxidant may be applied to the first surface and the second surface.

The first precursor is preferably be chosen of trimethylaluminium (TMA), trisdimethylamidosilane (TDMAS) and trisdimethylamidosilane (3DMAS), tetrakisdimethylaminosilane (4DMAS), N,N,N′,N′-tetraethyl silanediamine

The second precursor is preferably can be chosen as compound of one of the constitutional formulas M(R¹CP)₂(R²)₂ and M² R³ R⁴ R⁵ R⁶, wherein M is one of hafnium and zirconium, Cp is cyclopentadienyl, R¹ is independently selected of hydrogen, methyl, ethyl and alkyl, R² is independently selected of hydrogen, methyl, ethyl, alkyl, alkoxy, and halogen; and R³, R⁴, R⁵, and R⁶ are independently selected of alkyl amine.

The oxidant is preferably chosen of at least one of ozone, water, biatomic oxygen, ammonia, and hydrazine.

The etchable layer may be etched at least partly after the dielectric layer is deposited.

A trench may be formed into the substrate, the trench comprising a collar region defining the first surface and a bottle region defining the second surface.

According to a second aspect of the invention, a structured semiconductor comprises:

a substrate in which a trench is formed, the trench comprising a collar region, a bottle region and a interface region adjacent to the collar region and the bottle region;
an etchable layer contained of at least one of silicon oxide, silicon nitride, aluminium oxide, and aluminium nitride is formed in the collar region, but the bottle region is free of the etchable layer;
a dielectric layer of at least one of a transition metal oxide and a transition metal nitride is formed on the second surface;
and a mixed layer of the etchable layer and the dielectric layer in the interface region, wherein the part of the etchable layer in the mixed layer decreases steadily in a direction pointing towards the bottle region.

According to a third aspect of the invention, a memory device is provided, which comprises the structured semiconductor device of the second aspect of the invention.

### DESCRIPTION OF THE DRAWINGS

In the Figures:

FIG. 1 is a flow chart illustrating a first embodiment;

FIGS. 2-4 are cross sections of a capacitor structure formed in accordance with the first embodiment;

FIG. 5 is a flow chart illustrating a third embodiment; and

FIG. 6 is a flow chart illustrating a forth embodiment.

In the Figures, like numerals refer to the same or similar functionality throughout the several views.

### DETAILED DESCRIPTION OF THE INVENTION

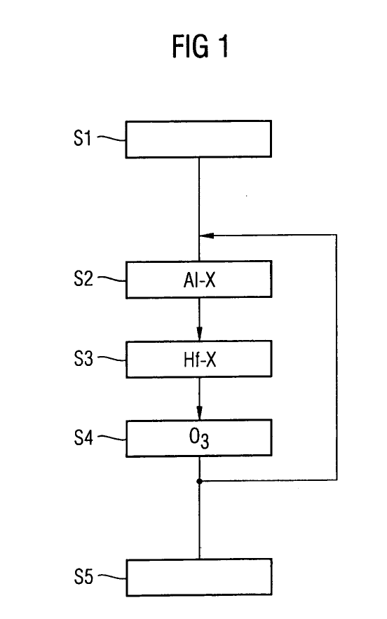

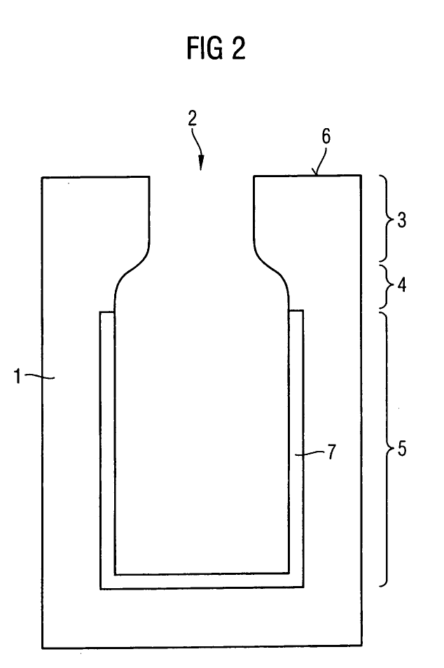

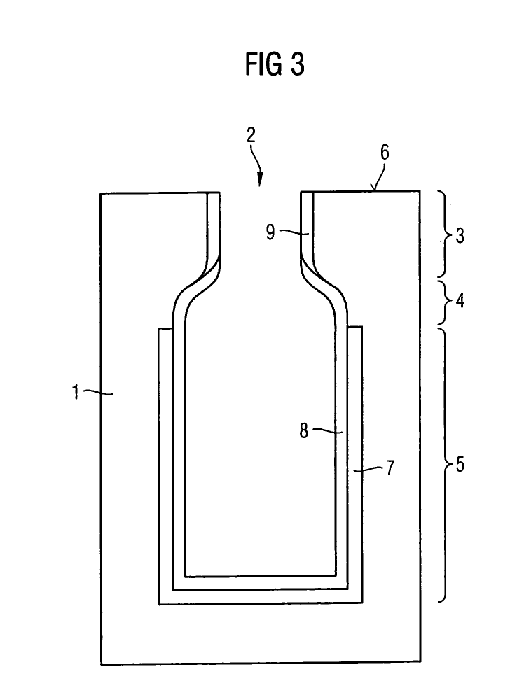

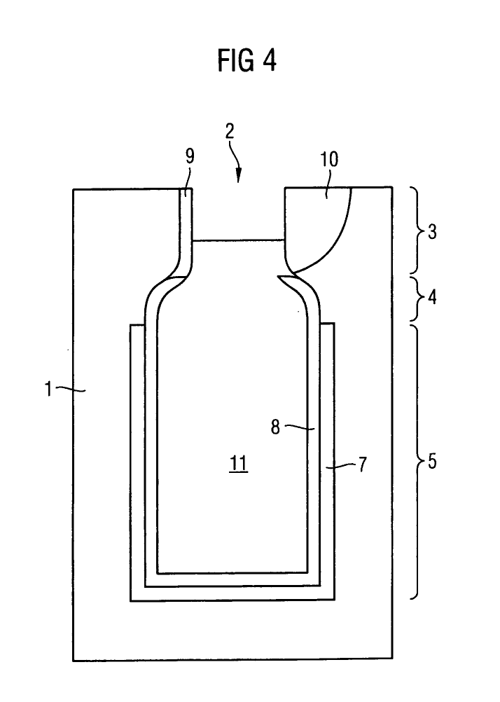

A first embodiment of the selective deposition method is going to be exemplarily described along with the flow diagram of FIG. 1 and the cross-sections shown along with FIGS. 2, 3 and 4.

A structured substrate 1 is provided (step S1). The substrate 1 may be of silicon or any other semiconductor material. Structures not shown may be formed into the substrate 1. These structures encompass active or passive electric components, electro optical components, optical components and micro-mechanical components or parts of the aforementioned components.

As an illustrative example a trench 2 is formed in the substrate 1. The trench 2 may consist of three regions: a collar region 3 close or adjacent to the opening of the trench 2, an intermediate region adjacent and below the collar region 3, and a bottle region 4 forming the lower part of the trench 2. The collar region 3 is provided closer to a principal top surface 6 of the substrate 1 compared to the bottle region 5.

Reactants used for the deposition method to be outlined herein are introduced in a direction towards the principle surface 6, either perpendicular in a single wafer processing chamber or under a small inclination with respect to the principle surface 6 in a multiple wafer processing chamber. In any case, the reactants first pass through the collar region 3 before the potentially reach the bottle region 5 of the trench 2.

Along side walls of the trench, a first electrode 7 may be formed.

A dielectric layer 8 made of hafnium oxide is deposited on the side walls of the trench 2 in the bottle region 5, i.e. on the first electrode 7. In the collar region 3, an etchable layer 9 of aluminium oxide is deposited. A mixture of aluminium oxide and hafnium oxide is deposited in the intermediate region 4. The concentration of the aluminium oxide increases towards the bottle region 5. The etchable layer 9 is named etchable as aluminium oxide can be etched with standard etch reactants without any remains. Known chemical etch reactants for crystalline hafnium oxide, however, all form hardly volatile etch products leading to remains inside trenches.

The deposition of the dielectric layer 8 in the bottle region 5 and the etchable layer 9 in the collar region 3 can be performed at the same time. A sketch on the method is given by the steps S2, S3, S4 in the flow diagram of FIG. 1.

The surface of the side walls in the trench 2 may be activated in a first step. Preferably, a reactant is introduced, which forms hydroxyl functional groups (—OH). The reactant can be for instance one of water (H₂O), ammonia (NH3) and hydrofluoric acid (HF).

A first precursor Al—X is introduced (step S2). The first precursor Al—X is an organic compound for transporting aluminium. The first precursor Al—X is chosen to have a high reactivity with hydroxyl functional groups. The first precursor Al—X reacts with the hydroxyl function groups and forms a layer comprising aluminium sticking to the side walls of the trench 2.

A crucial property of the first precursor Al—X is his high affinity to hydroxyl functional groups. The largest fraction of the first precursor Al—X reacts immediately with the surface in the collar region 3 as long as hydroxyl groups are present. Only a small, negligible fraction of the first precursor Al—X reaches the bottle region 5 without reaction and may react with the surface in the bottle region 5. A suitable first precursor are among other first precursors is trimethylaluminium Al(CH₃)₃.

The amount of the first precursor Al—X introduced in the reaction chamber is limited to an amount known to be insufficient to cover more than the side walls of the trench 2 in the collar region 3. Basically, test runs are necessary to determine the amount of the first precursor. Parameters to be controlled are the time of injection of the first precursor into a reaction chamber and the pressure in the reaction chamber. Exemplary parameters can be in the range of 0.1 to 0.2 seconds at a pressure of the first precursor in the range of 13-1300 Pa (0.1-10 Torr). It is understood that these parameters heavily depend on the dimensions of the side walls and structures to be covered with aluminium oxide Al₂O₃.

An inert purge gas may be used to ensure a transport of the first precursor to the surfaces and a removal of the first precursor out of the reaction chamber, such that the first precursor remains in the chamber for a well defined period corresponding to the pulse duration. The purge gas may be nitrogen or argon, for instance.

After step S2, hydroxyl groups in the collar region 3 have been subdued to a reaction and are thus removed; but the hydroxyl groups are still present in the bottle region 5. In a consecutive step S3, a second precursor Hf—X made of an organic compound transporting hafnium is introduced into the reaction chamber and into the trench 2. A deposition of a hafnium compound takes place where hydroxyl groups are present, hence basically only in the bottle region 5.

The second precursor can be chosen to be biscyclopentadienyl alkyl hafnium, i.e. of the formula Hf(R¹CP)₂(R²R³); Cp is cyclopentadienyl, R¹ is independently selected of hydrogen, methyl, ethyl and alkyl, R², R³ are independently selected of hydrogen H, methyl (CH₃), ethyl (C₂H₅), alkyl (CₙH₂ₙ₊₁), alkoxyl (—O—CₘH₂ₘ₊₁) and its halogenated derivates. Other groups of second precursors are of tetrakis alkyl amino hafnium, i.e. of the formula Hf R⁴ R⁵ R⁶ R⁷; R⁴, R⁵, R⁶, R⁷ are independently selected of alkyl amine (—N CₙH₂ₙ₊₁ CₘH₂ₘ₊₁).

The second precursor may be introduced in excess to provide a full reaction of all hydroxyl groups with the second precursor. The second precursor is introduced for a duration of about 1-60 seconds having a partial pressure of 13-1300 Pa (ca. 0.1-10 Torr).

The deposition is completed via an introduction of ozone (O₃) to the reaction chamber (step S3). The ozone transforms the chemically absorbed first and second precursors to aluminium oxide and hafnium oxide, respectively. Further, ozone is used to form new hydroxyl groups on the aluminium oxide and the hafnium oxide.

In case an oxidant is used which does not form new hydroxyl groups on the aluminium oxide in the collar region 3, a newly introduction of the first precursor is to be omitted in order to avoid a deposition of aluminium oxide in the bottle region 5.

The steps S2, S3, and S4 can be repeated several times until a desired thickness of the dielectric layer 9 and the etchable layer 8 are achieved.

The etchable layer 8 can be partly removed by an etch process at one side of the collar (step S5). A conductive area 10 can be formed in the collar region 3 at the side the etchable layer 8 is removed. A counter electrode 11 may be filled into the trench 2 up to the conductive area 10.

The first embodiment taught along with FIG. 1 only applies ozone after both the first precursor Al—X and the second precursor Hf—X were introduced into the reaction chamber. A second embodiment applies the oxidant, e.g. ozone, consecutively after the first precursor Al—X was introduced and applies the oxidant consecutively after the second precursor Hf—X was introduced.

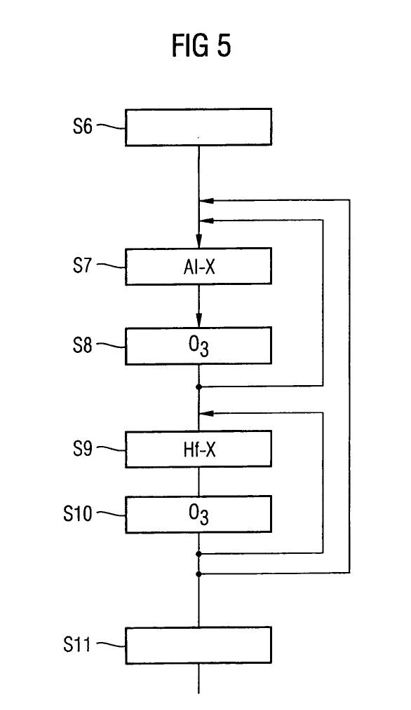

A third embodiment is illustrated along with a flow diagram of FIG. 5. A substrate covered with hydroxyl groups is provided in step S6 which is identical or similar to step S1 of the first embodiment. An first precursor Al—X comprising aluminium is introduced in a limited amount and chemisorbs to the hydroxyl-groups in a collar region 3 (step 7). The amount of the first precursor Al—X reacting with the substrate be controlled by the partial pressure of the first precursor Al—X and the duration the first precursor Al—X remains in the reaction chamber, for a detailed example of the parameters and precursors used see the first embodiment. An oxidant, e.g. ozone, is introduced to transform the chemisorbed first precursor Al—X to aluminium oxide and to provide new hydroxyl groups (step 8). An aluminium oxide layer of a specified thickness may be achieved by repeating the steps 7 and 8 several times.

Hafnium oxide is deposited is deposited in the bottle region 5 by use of a second precursor and an oxidant (steps 9, 10). The second precursor may be one of the precursors taught along with the first embodiment. Several molecular layers may be deposited by repeating steps 9 and 10. This embodiment deposits a hafnium oxide layer in the collar region 3, as well. Hydroxyl groups are present in the collar region 3 due to the repeated use of the oxidant. Anyhow, the concentration of hafnium in the collar region is reduced due to the underlying aluminium oxide. A new layer of aluminium oxide may be deposited in the collar region 3 again after the deposition of hafnium oxide. The layers made of aluminium oxide and hafnium oxide can be removed by standard etchants with negligible remains.

The further processing (step 10) can be similar or identical to step 5 of the first embodiment.

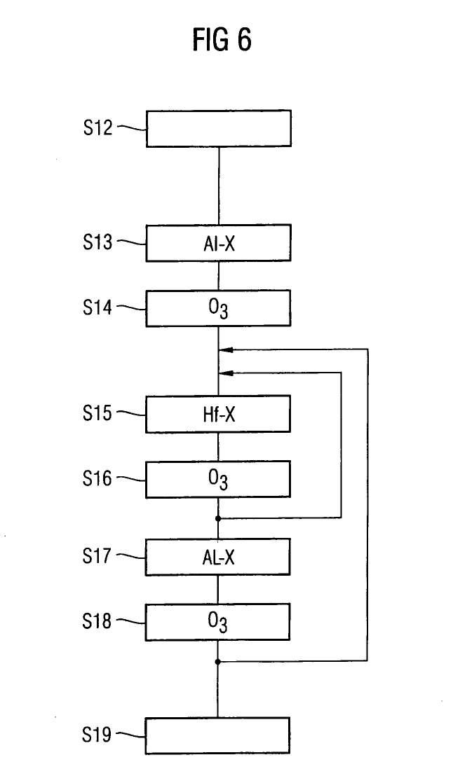

A forth embodiment can be based on the first or the third embodiment (FIG. 6). In the bottle region a minor contribution of aluminium oxide is deposited. Step 12 is identical to steps 1 and 6. Aluminium oxide is selectively deposited in the collar region 3 by a limited use of the first precursor Al—X, as taught along with the first and third embodiment (steps S13, S14). A layer of hafnium oxide is deposited in the bottle region (steps S15, S16). Additionally, a few, preferably one or two monolayers of aluminium oxide are deposited in the bottle region 5. The ratio of hafnium or other transition metals compared to aluminium or other non transition metals is greater than 2:1. The aluminium is used as dopant that stabilizes the crystal structure of hafnium oxide, an other preferred dopant is silicon. The same ratio is below 2:1 in the collar region 3. The composition in the collar region needs to be easily etched, hence the different ratios are favoured. The manufacturing of the semiconductor device can be continued by step 19 alike step 5.

The above embodiments are described for the deposition of the preferred example hafnium oxide and aluminium oxide. Other materials and precursors may be useful, too. Zirconium is a further transition metal having an oxide of promising electrical properties. The above examples can be performed by replacing hafnium by zirconium in all compounds listed herein. Mixtures using both hafnium and zirconium can be used, as well. A deposition of transition metal nitrides can be performed, too.

Silicon oxide can be used instead of or additional to aluminium oxide. A preferred first precursor for a deposition of silicon oxide is trisdimethylaminosilane.

The oxidant ozone can be substituted by one of biatomic oxygen (O₂), water, ammonia and hydrazine. The use of ammonia and hydrazine leads to the formation of transition metal nitrides instead of transition metal oxides.

Although the present invention has been described with reference to a preferred embodiment, it is not limited thereto, but can be modified in various manners which are obvious for persons skilled in the art. Thus, it is intended that the present invention is only limited by the scope of the claims attached herewith.

The above examples refer to the formation of capacitors. The present invention can also be applied to the formation of other structured devices. The etchable layer is always deposited on surfaces which come first into contact with the first precursor. These surfaces may be top surfaces of any structures extending from the principle surface. The other surfaces will be cover with the transition metal compound.

1. A selective deposition method, comprising the steps of:
(a) providing a substrate being structured to comprise a first surface and a second surface, which differ in at least one of geometric orientation and vertical distance to a principle surface of the substrate;
(b) depositing an etchable layer on the first surface via an atomic layer deposition technique the deposition technique using a first precursor supplied in an amount sufficient to cover at least parts of the first surface and insufficient to cover the second surface, the first precursor being supplied from a direction to pass the first surface before the second surface;
(c) depositing a dielectric layer of at least one of a transition metal oxide and a transition metal nitride on at least the second surface via an atomic layer deposition technique using a second precursor.

2. The selective deposition method according to claim 1, wherein the etchable layer on the first surface and the dielectric layer on the second layer are deposited alternatingly.

3. The selective deposition method according to claim 1, wherein consecutively the first precursor is applied to the first surface, the second precursor is applied to at least the second surface, and an oxidant is applied to the first surface and the second surface.

4. The selective deposition method according to claim 1, wherein the first precursor is at least one of the group of trimethylaluminium (TMA), trisdimethylaminosilane (TDMAS), tertrakis(dimethylamino)silane (3DMAS), tetrakisdimethylaminosilane (4DMAS), N,N,N′,N′-tetraethyl silanediamine.

5. The selective deposition method according to claim 1, wherein the second precursor is a compound having one of the constitutional formulas M (R¹Cp)₂(R²)₂ and M² R³ R⁴ R⁵ R⁶, wherein M is one of hafnium and zirconium, Cp is cyclopentadienyl, R¹ is independently selected of hydrogen, methyl, ethyl and alkyl, R² is independently selected of hydrogen, methyl, ethyl, alkyl, alkoxy, halogen, and R³, R⁴, R⁵, and R⁶ are independently selected of alkyl amine.

6. The selective deposition method according to claim 1, wherein the oxidant is at least one of ozone, water, biatomic oxygen, ammonia, and hydrazine.

7. The selective deposition method according to claim 1, wherein the etchable layer is at least partly etched after the dielectric layer is deposited.

8. The selective deposition method according to claim 1, wherein a trench is formed into the substrate, the trench comprising a collar region defining the first surface and a bottle region defining the second surface.

9. A structured semiconductor device, comprising:
a substrate in which a trench is formed, the trench comprising a collar region, a bottle region and a interface region adjacent to the collar region and the bottle region;
an etchable layer made of at least one of silicon oxide, silicon nitride, aluminium oxide, and aluminium nitride is formed in the collar region, but the bottle region is free of the etch able layer;
a dielectric layer of at least one of a transition metal oxide and a transition metal nitride is formed on the second surface;
and a mixed layer of the etchable layer and the dielectric layer in the interface region, wherein the part of the etchable layer in the mixed layer decreases steadily in a direction pointing towards the bottle region.

10. A memory device comprising the structured semiconductor device according to claim 9.
